(19) United States
(12) Patent Application Publication
(10) Pub. No.: US 2026/0344183 A1
(43) Pub. Date: Oct. 29, 2026

(54) FABRICATION METHOD FOR DISPLAY PANEL, AND DISPLAY DEVICE

(71) Applicant: Visionox Technology Inc., Kunshan (CN)

(72) Inventors: Junwei LIU, Kunshan (CN); Huanhuan ZHANG, Kunshan (CN); Guofei KANG, Kunshan (CN); Junhui LOU, Kunshan (CN); Min ZHANG, Kunshan (CN); Yonglei XU, Kunshan (CN); Jinliang LIU, Kunshan (CN)

(73) Assignee: Visionox Technology Inc., Kunshan (CN)

(21) Appl. No.: 19/433,939

(22) Filed: Dec. 28, 2025

(30) Foreign Application Priority Data
Apr. 28, 2025 (CN) 202510546994.5

(51) Int. Cl. H10K 59/12; H10K 71/20; H10K 102/00

(52) U.S. Cl. CPC H10K 59/1201; H10K 71/231; H10K 2102/351

(57) ABSTRACT

The present application discloses a fabrication method for a display panel, and a display device. A first emissive material layer is prepared on a substrate, a first barrier material layer is then prepared on a side of the first emissive material layer facing away from the substrate, and a first sacrificial material layer is then prepared on a side of the first barrier material layer facing away from the substrate, and the first barrier material layer separates the first emissive material layer from the first sacrificial material layer.

### CROSS-REFERENCE TO RELATED APPLICATIONS

The present application claims priority to Chinese Patent Application No. 202510546994.5, entitled "FABRICATION METHOD FOR DISPLAY PANEL, AND DISPLAY DEVICE" and filed on Apr. 28, 2025, which is incorporated herein by reference in its entirety.

### FIELD

The present application relates to the field of display, and in particular, to a fabrication method for a display panel, and a display device.

### BACKGROUND

Organic light-emitting diodes (OLED) and flat-panel display devices based on technologies such as light-emitting diodes (LED) are widely used in various consumer electronics such as mobile phones, televisions, notebook computers, and desktop computers, and predominate in display devices, due to their advantages such as high image quality, energy efficiency, slim design, and a wide range of applications.

During the fabrication of conventional display panels, light-emitting pixel patterning is typically implemented using a fine metal mask (FMM). FMM technology is mature and has rich experience in mass production. However, the FMM technology also has problems such as limited accuracy, high development costs, and a long development cycle. Fine metal mask-free technology eliminates the limitations of conventional OLED processes on display size, resolution, and other screen performances, and has the advantages of high performance, full-size coverage, and agile delivery. Reference can be made to relevant contents of the fine metal mask-free technology recited in Chinese patents CN118251982A, CN115666161A, CN116648095A, CN117062489A, CN118678742A, CN118785761A, CN115224220A, CN118678729A, CN118660529A, and CN118660589A.

However, the usage performance of current OLED display products needs to be improved.

### SUMMARY

Embodiments of the present application provide a fabrication method for a display panel, and a display device, which are intended to improve the usage performance of OLED display products.

Embodiments of the present application provide a fabrication method, including:
preparing a first emissive material layer on a substrate;
preparing a first barrier material layer on a side of the first emissive material layer facing away from the substrate by means of vacuum evaporation deposition;
preparing a first sacrificial material layer on a side of the first barrier material layer facing away from the substrate;
preparing a first etch protection layer on a side of the first sacrificial material layer facing away from the substrate, where the first etch protection layer includes a plurality of spaced-apart first etch protection portions; and
patterning the first emissive material layer, the first barrier material layer, and the first sacrificial material layer to form a first light-emitting structure, a first barrier portion, and a first sacrificial portion in a region corresponding to each first etch protection portion.

Embodiments of the present application provide a display device, including a display panel fabricated by a fabrication method of any one of the above implementations.

### BRIEF DESCRIPTION OF THE DRAWINGS

Embodiments of the present application will become apparent upon reading the following detailed description of non-limiting embodiments with reference to the drawings, where identical or similar reference numerals indicate identical or similar features and the drawings are not drawn to scale.

FIG. 1 is a flowchart of a fabrication method for a display panel according to an embodiment of the present application;

FIGS. 2 to 12 are diagrams of a fabrication process of a display panel according to an embodiment of the present application;

FIG. 13 is a partial cross-sectional view of a display panel according to an embodiment of the present application;

FIG. 14 is a partial cross-sectional view of a display panel according to another embodiment; and

FIG. 15 is a partial cross-sectional view of a display panel according to yet another embodiment.

List of reference signs: 10. Display panel; 100. Substrate; 210. First emissive material layer; 211. First light-emitting structure; 220. Second emissive material layer; 221. Second light-emitting structure; 230. Third emissive material layer; 231. Third light-emitting structure; 310. First barrier material layer; 311. First barrier portion; 311a. First sub-layer; 311b. Second sub-layer; 320. Second barrier material layer; 321. Second barrier portion; 321a. Third sub-layer; 321b. Fourth sub-layer; 330. Third barrier material layer; 331. Third barrier portion; 331a. Fifth sub-layer; 331b. Sixth sub-layer; 410. First sacrificial material layer; 411. First sacrificial portion; 420. Second sacrificial material layer; 421. Second sacrificial portion; 430. Third sacrificial material layer; 431. Third sacrificial portion; 440. First etch protection layer; 441. First etch protection portion; 450. Second etch protection layer; 451. Second etch protection portion; 460. Third etch protection layer; 461. Third etch protection portion; 500. Isolation structure; 510. First layer; 520. Second layer; 530. Third layer; 540. Isolation opening; 600. First electrode layer; 610. First electrode; 700. Pixel define layer; 710. Pixel defining portion; 720. Pixel opening; 730. Second electrode.

### DETAILED DESCRIPTION OF THE EMBODIMENTS

Features and exemplary embodiments in various aspects of the present application will be described in detail below. In order to make the objectives, technical solutions, and advantages of the present application clearer, the present application will be further described in detail below with reference to the accompanying drawings and specific embodiments. It should be understood that the specific embodiments described herein are merely configured to explain the present application and are not configured to limit the present application. The present application may be implemented without part of these specific details. The following description of the embodiments is merely to provide a better understanding of the present application by illustrating examples of the present application.

It should be noted that, herein, relational terms such as "first" and "second" are only used to distinguish one entity or operation from another entity or operation, and do not necessarily require or imply that such an actual relationship or order exists between these entities or operations. Furthermore, the terms “include”, “comprise”, or any other variant thereof are intended to encompass non-exclusive inclusion, and a process, method, article, or device including a series of elements includes not only those elements, but also other elements not explicitly listed, or elements inherent to such a process, method, article, or device. If no more limitations are made, an element limited by "including..." does not exclude other identical elements existing in the process, the method, the article, or the device which includes the element.

It should be understood that in the description of the structure of a component, a layer or region referred as being located "above" or "over" another layer or region may be directly on the other layer or region, or there may be other layers or regions between the layer or region and the other layer or region. Moreover, when the component is turned over, the layer or region is located "below" or "under" the other layer or region.

The embodiments of the present application provide a fabrication method for a display panel 10, and a display device. The embodiments of the fabrication method for a display panel 10 and the embodiments of the display device are described below with reference to the drawings.

According to the embodiments of the present application, the fabrication method for a display panel 10 may be a fabrication method for an organic light-emitting diode (OLED) display panel 10.

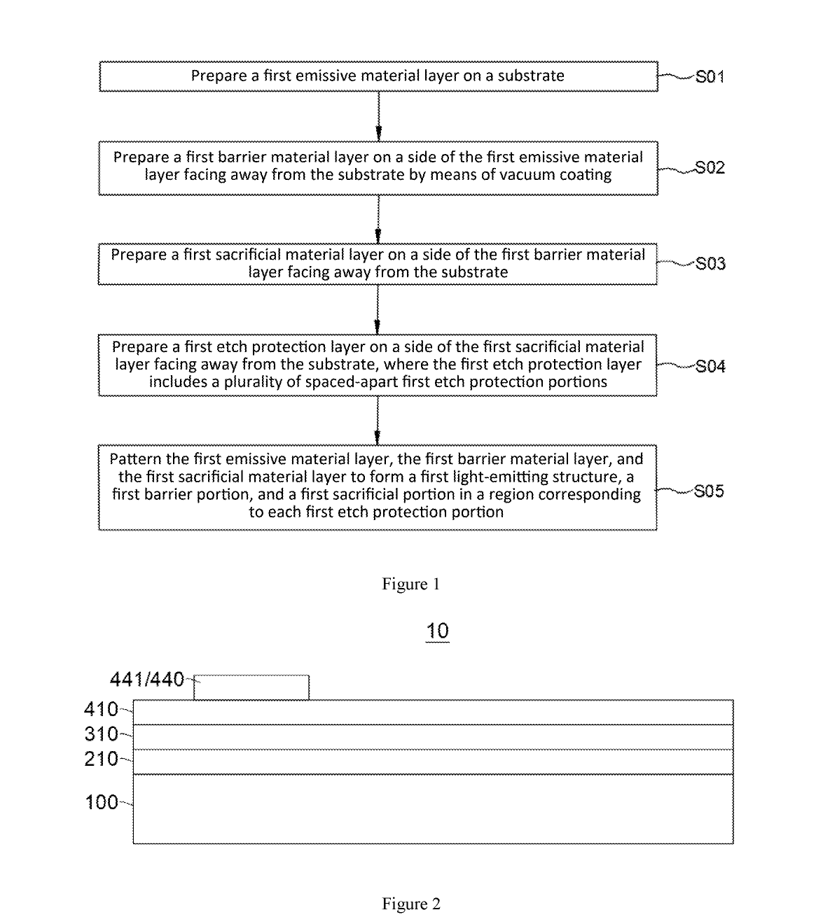

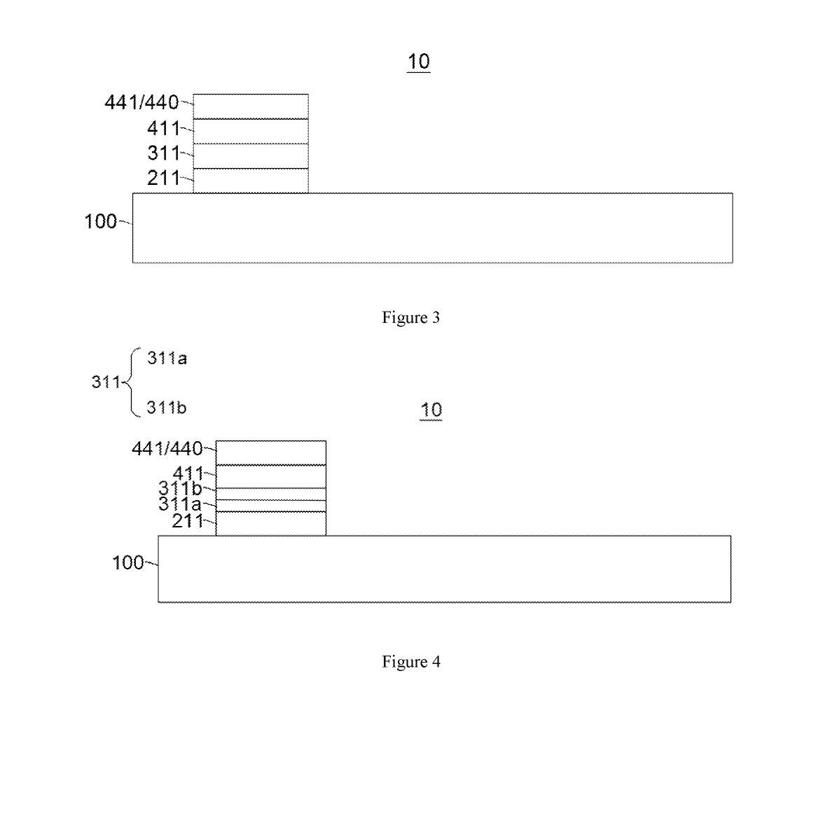

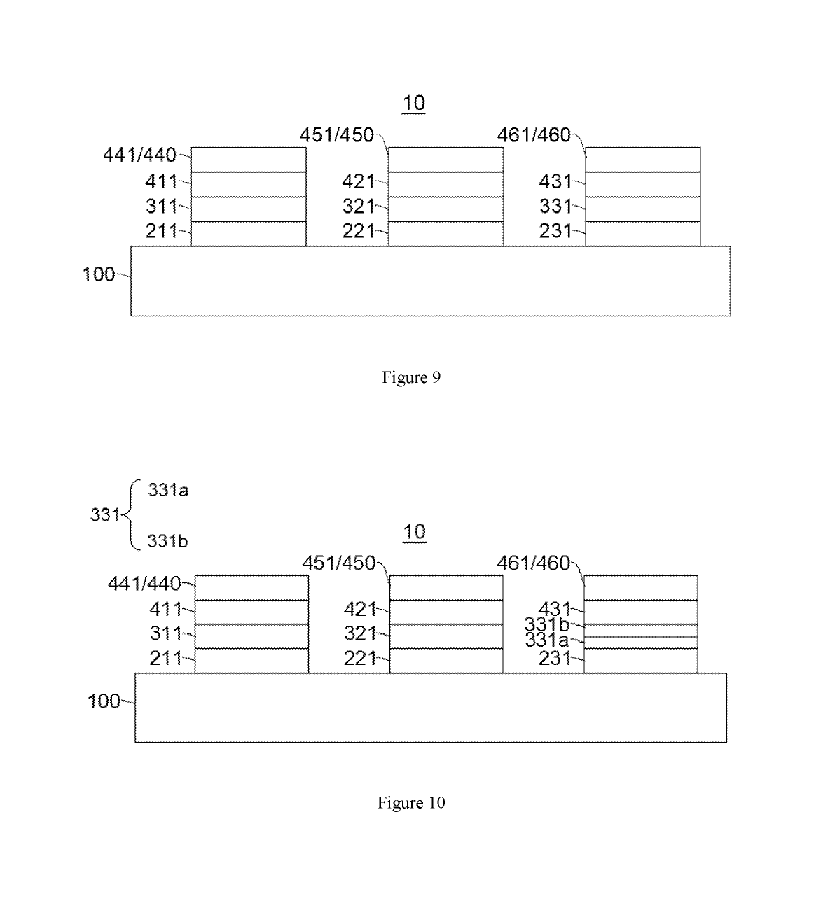

Referring to FIGS. 1 to 12, FIG. 1 is a flowchart of a fabrication method for a display panel according to an embodiment of the present application; and FIGS. 2 to 12 are diagrams of a fabrication process of a display panel according to an embodiment of the present application.

As shown in FIGS. 1 to 12, the embodiments of the present application provide a fabrication method, including: step S01: preparing a first emissive material layer 210 on a substrate 100; step S02: preparing a first barrier material layer 310 on a side of the first emissive material layer 210 facing away from the substrate 100 by means of vacuum evaporation deposition; step S03: preparing a first sacrificial material layer 410 on a side of the first barrier material layer 310 facing away from the substrate 100; step S04: preparing a first etch protection layer 440 on a side of the first sacrificial material layer 410 facing away from the substrate 100, where the first etch protection layer 440 includes a plurality of spaced-apart first etch protection portions 441; and step S05: patterning the first emissive material layer 210, the first barrier material layer 310, and the first sacrificial material layer 410 to form a first light-emitting structure 211, a first barrier portion 311, and a first sacrificial portion 411 in a region corresponding to each first etch protection portions 441. According to the fabrication method for a display panel 10 according to the embodiments of the present application, preparing the first emissive material layer 210 on the substrate 100 in step S01, the first barrier material layer 310 on the side of the first emissive material layer 210 facing away from the substrate 100 in step S02, and then the first sacrificial material layer 410 on the side of the first barrier material layer 310 facing away from the substrate 100 in step S03 enables the first barrier material layer 310 to separate the first emissive material layer 210 from the first sacrificial material layer 410, thereby avoiding damage to the first emissive material layer 210 during the preparation of the first sacrificial material layer 410. In step S04, continuously preparing on the first sacrificial material layer 410 the first etch protection layer 440 including the plurality of first etch protection portions 441 enables the plurality of first etch protection portions 441 to provide etch protection for the first emissive material layer 210, the first barrier material layer 310, and the first sacrificial material layer 410, and in step S05, the first emissive material layer 210, the first barrier material layer 310, and the first sacrificial material layer 410 are retained in the region where each first etch protection portion 441 is located, and parts thereof in other regions are etched away, thereby forming the first light-emitting structure 211, the first barrier portion 311, and the first sacrificial portion 411. The first barrier material layer 310 being prepared by means of vacuum evaporation deposition can reduce damage to the first emissive material layer 210 during the preparation of the first barrier material layer 310, and minimize damage to a surface of the first light-emitting structure 211 after the subsequent peeling off and removal of the first barrier portion 311, the first sacrificial portion 411, and the first etch protection portion 441, thereby improving the device performance of the first light-emitting structure 211 and the usage performance of the display panel 10.

In some embodiments, the vacuum evaporation deposition method includes physical vapor deposition (PVD), such as vacuum evaporation coating, vacuum sputtering coating, or vacuum ion plating. These are all dry coating processes that do not involve thermal curing, thereby reducing damage to the first emissive material layer 210.

In some embodiments, a material of the first etch protection portions 441 includes a photoresist.

In some embodiments, step S03 includes:
applying a solution including the first sacrificial material on the side of the first barrier material layer 310 facing away from the substrate 100; and
thermally curing the solution including the first sacrificial material to form the first sacrificial material layer 410.

In these embodiments, after the solution including the first sacrificial material is applied on a surface of the first barrier material layer 310, the solution including the first sacrificial material is heated to evaporate the solvent of the first sacrificial material, thereby forming the first sacrificial material layer 410. In the related art, the solution including the first sacrificial material is directly applied on the first emissive material layer 210 and is thermally cured to form the first sacrificial material layer 410. Such thermal curing may lead to damage to the first emissive material layer 210, leading to an increase in voltage and a decrease in lifetime of the first light-emitting structure 211 after

the subsequent peeling off of the first sacrificial material layer 410. Moreover, after the first sacrificial material layer 410 is formed by thermal curing, the adhesion of the first sacrificial material layer 410 to the first emissive material layer 210 is relatively high, making it difficult to completely peel off the first sacrificial material layer 410. This results in residues of the first sacrificial material layer 410 remaining on the surface of the first light-emitting structure 211, leading to an increase in voltage and a decrease in lifetime of the first light-emitting structure 211. Therefore, in the present application, the first barrier material layer 310 is disposed between the first sacrificial material layer 410 and the first emissive material layer 210, which can avoid the adverse effects of thermal curing of the first sacrificial material layer 410 on the first emissive material layer 210.

The substrate 100 may be configured in various ways. For example, the substrate 100 may include a base substrate and an array substrate disposed on the base substrate. In one embodiment, the substrate 100 may serve as the base substrate. In one embodiment, the substrate 100 includes a buffer layer, a support plate, etc. on a side facing away from the base substrate.

In some embodiments, a material of the first sacrificial material layer 410 includes an organic material, such as a polymer resin, with water as the solvent.

In some embodiments, a solubility of the first barrier portion 311 in water is greater than or equal to 10⁻⁴ g/100 mL, which can address the problem of an excessively low solubility of the first barrier portion 311 in water making it difficult to completely remove the first barrier portion 311 during subsequent dissolution and removal of the first barrier portion 311 using an aqueous solvent, resulting in residues remaining on the surface of the first light-emitting structure 211, and thus leading to an increase in voltage and a decrease in lifetime of the first light-emitting structure 211.

In some embodiments, the solubility of the first barrier portion 311 in water ranges from 10⁻⁴ to 10⁻² g/100 mL. For example, the solubility of the first barrier portion 311 in water may be 10⁻⁴ g/100 mL, 3 × 10⁻⁴ g/100 mL, 10⁻³ g/100 mL, or 10⁻² g/100 mL. In the present application, the solubility refers to a solubility at room temperature (20°C).

In these embodiments, the solubility of the first barrier portion 311 in water is greater than or equal to 10⁻⁴ g/100 mL, which can address the problem of an excessively low solubility of the first barrier portion 311 in water making it difficult to completely remove the first barrier portion 311 during subsequent dissolution and removal of the first barrier portion 311 using an aqueous solvent, resulting in residues remaining on the surface of the first light-emitting structure 211, and thus leading to an increase in voltage and a decrease in lifetime of the first light-emitting structure 211. The solubility of the first barrier portion 311 in water is less than or equal to 10⁻² g/100 mL, which can address the problem of an excessively high solubility of the first barrier portion 311 in water causing the solvent in the first sacrificial material layer 410 to tend to completely dissolve the first barrier portion 311 during the preparation of the first sacrificial material layer 410, leading to damage to the first emissive material layer 210 during thermal curing of the first sacrificial material layer 410, or making it difficult to completely remove the first sacrificial material layer 410 subsequently, and thus resulting in residues remaining on the surface of the first light-emitting structure 211.

In some embodiments, a material of the first barrier portion 311 includes an organic material or an inorganic material, and the organic material may include, for example, 8-hydroxyquinoline, etc.

In some embodiments, the inorganic material includes a metal compound, such as calcium fluoride, magnesium fluoride, or lithium fluoride. The metal compound has a relatively low solubility, making it difficult to be dissolved by the solvent of the first sacrificial material layer 410, and allowing subsequent dissolution and removal using an aqueous solvent. The solubility of calcium fluoride in water is 8.575 × 10⁻³ g/100 mL, and the solubility of magnesium fluoride in water is 7.325 × 10⁻³ g/100 mL.

In some embodiments, the first barrier portion 311 has a thickness of 50 Å to 1000 Å. For example, the thickness of the first barrier portion 311 may be 50 Å, 100 Å, 500 Å, or 1000 Å. In the present application, the thickness refers to a dimension in a thickness direction of the display panel 10.

In these embodiments, the thickness of the first barrier portion 311 is greater than or equal to 50 Å, which can address the problem of an excessively small thickness of the first barrier portion 311 causing the solvent in the first sacrificial material layer 410 to tend to completely dissolve the first barrier portion 311 during the preparation of the first sacrificial material layer 410, leading to damage to the first emissive material layer 210 during thermal curing of the first sacrificial material layer 410, or making it difficult to completely remove the first sacrificial material layer 410 subsequently, and thus resulting in residues remaining on the surface of the first light-emitting structure 211. The thickness of the first barrier portion 311 is less than or equal to 1000 Å, which can address the problem of an excessively large thickness of the first barrier portion 311 resulting in increased material cost and greater difficulty in subsequent dissolution and removal of the first barrier portion 311, resulting in residues remaining.

As shown in FIGS. 2 and 4, in some embodiments, the first barrier material layer 310 includes a first material layer and a second material layer, and preparing the first barrier material layer 310 on the side of the first emissive material layer 210 facing away from the substrate 100 by means of vacuum evaporation deposition includes: sequentially preparing the first material layer and the second material layer on the side of the first emissive material layer 210 facing away from the substrate 100.

In some embodiments, patterning the first emissive material layer 210, the first barrier material layer 310, and the first sacrificial material layer 410 includes: patterning the first material layer and the second material layer to form the first barrier portion 311, where the first barrier portion 311 includes a first sub-layer 311aand a second sub-layer 311b, and the second sub-layer 311bis located on a side of the first sub-layer 311afacing away from the substrate 100.

In these embodiments, the first barrier material layer 310 is prepared in two steps as the first material layer and the second material layer, and the first material layer and the second material layer form the first sub-layer 311a and the second sub-layer 311b, respectively, and solubilities of the first sub-layer 311a and the second sub-layer 311b can be individually controlled, thereby facilitating the separation of the first sacrificial portion 411 from the first light-emitting structure 211 and enabling easy subsequent dissolution and removal.

In some embodiments, the solubility of the second sub-layer 311b in water is lower than the solubility of the first sub-layer 311a in water.

In these embodiments, the second sub-layer 311b has a lower solubility in water, and during the preparation of the first sacrificial material layer 410, the solvent of the first sacrificial material layer 410 is difficult to completely dissolve the second sub-layer 311b, thereby achieving separation of the first sacrificial portion 411 from the first light-emitting structure 211. The first sub-layer 311ahas a higher solubility in water, and during subsequent dissolution and removal of the first barrier portion 311 using an aqueous solvent, the first sub-layer 311ais easy to be completely dissolved by the water, thereby achieving peeling off of the first sub-layer 311aand the second sub-layer 311b.

In some embodiments, the solubility of the second sub-layer 311bin water ranges from 10⁻⁴ to 10⁻² g/100 mL. For example, the solubility of the second sub-layer 311b in water may be 10⁻⁴ g/100 mL, 3 × 10⁻⁴ g/100 mL, 10⁻³ g/100 mL, or 10⁻² g/100 mL. The second sub-layer 311bhas a relatively low solubility in water, and during the preparation of the first sacrificial material layer 410, the solvent of the first sacrificial material layer 410 is difficult to completely dissolve the second sub-layer 311b, thereby achieving separation of the first sacrificial portion 411 from the first light-emitting structure 211.

In some embodiments, the solubility of the second sub-layer 311b in water is less than or equal to 10⁻⁴ g/100 mL. For example, the solubility of the second sub-layer 311bin water may be 10⁻⁷ g/100 mL, 10⁻⁶ g/100 mL, 10⁻⁵ g/100 mL, or 10⁻⁴ g/100 mL, etc. The second sub-layer 311bhas a relatively low solubility in water, and during the preparation of the first sacrificial material layer 410, the solvent of the first sacrificial material layer 410 is difficult to completely dissolve the second sub-layer 311b, thereby achieving separation of the first sacrificial portion 411 from the first light-emitting structure 211.

In some embodiments, the solubility of the first sub-layer 311a in water is greater than or equal to 0.1 g/100 mL. For example, the solubility of the first sub-layer 311ain water may be 0.1 g/100 mL, 0.27 g/100 mL, 1 g/100 mL, or 2 g/100 mL. The first sub-layer 311ahas a relatively high solubility in water, and during subsequent dissolution and removal of the first barrier portion 311 using an aqueous solvent, the first sub-layer 311ais easy to be completely dissolved by the water, thereby achieving peeling off of the first sub-layer 311aand the second sub-layer 311b.

In some embodiments, a material of the second sub-layer 311bincludes an inorganic material, such as calcium fluoride, magnesium fluoride, or a cathode material, or an organic material, such as a hole blocking material or an electron transport material, all of which have relatively low solubility.

In some embodiments, a material of the first sub-layer 311aincludes an organic material or an inorganic material, such as lithium fluoride or 8-hydroxyquinoline, all of which have relatively high solubility.

In some embodiments, a thickness of the second sub-layer 311b is less than a thickness of the first sub-layer 311a.

In these embodiments, the second sub-layer 311b has a smaller thickness, which reduces material costs and facilitates easier peeling off of the second sub-layer 311bduring subsequent dissolution of the first sub-layer 311a using an aqueous solvent. The first sub-layer 311ahas a larger thickness, which can more effectively separate the first emissive material layer 210 from the first sacrificial material layer 410, and avoid the problem of an excessively small thickness of the first sub-layer 311aresulting in partial adhesion of the second sub-layer 311bto the surface of the first light-emitting structure 211 after dissolution and removal of the first sub-layer 311ausing an aqueous solvent, making it difficult to completely peel off the second sub-layer.

In some embodiments, the thickness of the first sub-layer 311a ranges from 50 Å to 1000 Å. For example, the thickness of the first sub-layer 311amay be 50 Å, 100 Å, 500 Å, or 1000 Å, etc.

In these embodiments, the thickness of the first sub-layer 311ais greater than or equal to 50 Å, which can address the problem of an excessively small thickness of the first sub-layer 311aresulting in partial adhesion of the second sub-layer 311bto the surface of the first light-emitting structure 211 after dissolution and removal of the first sub-layer 311a using an aqueous solvent, making it difficult to completely peel off the second sub-layer. The thickness of the first sub-layer 311ais less than or equal to 1000 Å, which can address the problem of an excessively large thickness of the first sub-layer 311aresulting in increased material cost and greater difficulty in subsequent dissolution and removal of the first sub-layer 311a, resulting in residues remaining.

In some embodiments, the thickness of the second sub-layer 311b ranges from 2 Å to 50 Å. For example, the thickness of the second sub-layer 311b may be 2 Å, 10 Å, 20 Å, or 50 Å, etc.

In these embodiments, the thickness of the second sub-layer 311bis greater than or equal to 2 Å, which can address the problem of an excessively small thickness of the second sub-layer 311bresulting in greater difficulty in the preparation process of the second sub-layer 311band making the second sub-layer 311bprone to being completely dissolved by the solvent of the first sacrificial material layer 410, thereby further dissolving the first sub-layer 311a. This may lead to damage to the first emissive material layer 210 during thermal curing of the first sacrificial material layer 410, or make it difficult to completely remove the first sacrificial material layer 410 subsequently, resulting in residues remaining on the surface of the first light-emitting structure 211.

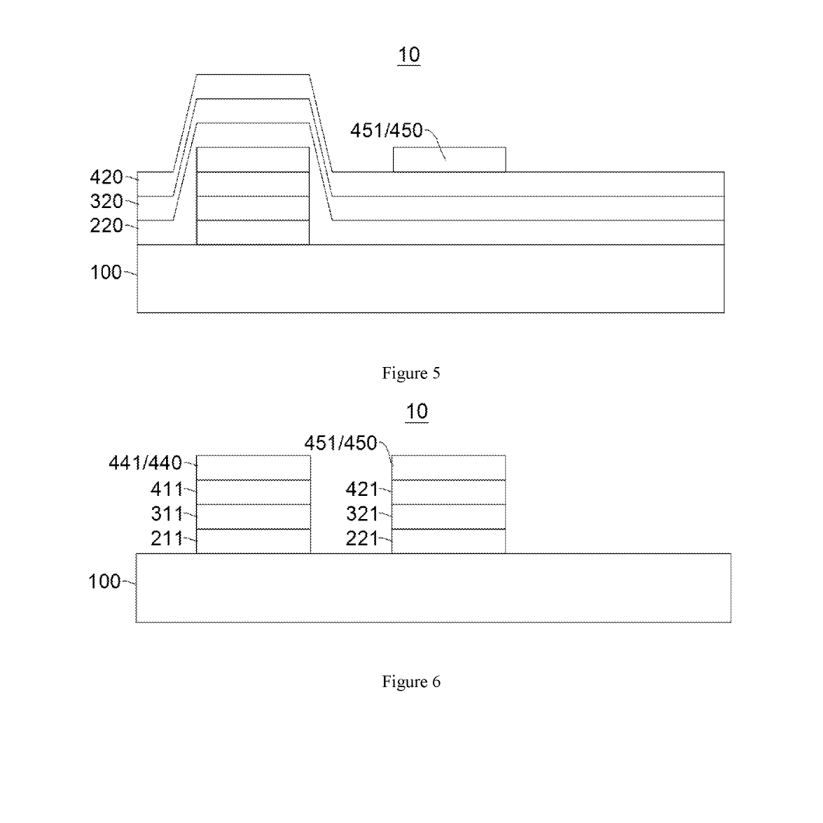

As shown in FIGS. 5 to 7, in some embodiments, the method further includes, posterior to patterning the first emissive material layer 210, the first barrier material layer 310, and the first sacrificial material layer 410 to form the first light-emitting structure 211, the first barrier portion 311, and the first sacrificial portion 411, preparing a second emissive material layer 220 on the substrate 100; preparing a second barrier material layer 320 on a side of the second emissive material layer 220 facing away from the substrate 100 by means of vacuum evaporation deposition; preparing a second sacrificial material layer 420 on a side of the second barrier material layer 320 facing away from the substrate 100; preparing a second etch protection layer 450 on a side of the second sacrificial material layer 420 facing away from the substrate 100, where the second etch protection layer 450 includes a plurality of spaced-apart second etch protection portions 451; and patterning the second emissive material layer 220, the second barrier material layer 320, and the second sacrificial material layer 420 to form a second light-emitting structure 221, a second barrier portion 321, and a second sacrificial portion 421 in a region corresponding to each second etch protection portions 451.

In these embodiments, after step S05, sequentially preparing the second emissive material layer 220 and the second barrier material layer 320 on the substrate 100, and then the second sacrificial material layer 420 on the side of the second barrier material layer 320 facing away from the substrate 100 enables the second barrier material layer 320 to separate the second emissive material layer 220 from the second sacrificial material layer 420, thereby avoiding damage to the second emissive material layer 220 during the preparation of the second sacrificial material layer 420. Continuously preparing on the second sacrificial material layer 420 the second etch protection layer 450 including the plurality of second etch protection portions 451 enables the plurality of second etch protection portions 451 to provide etch protection for the second emissive material layer 220, the second barrier material layer 320, and the second sacrificial material layer 420, and the second emissive material layer 220, the second barrier material layer 320, and the second sacrificial material layer 420 are retained in the region where each second etch protection portions 451 is located, and parts thereof in other regions are etched away, thereby forming the second light-emitting structure 221, the second barrier portion 321, and the second sacrificial portion 421. The second barrier material layer 320 being formed by means of vacuum evaporation deposition can reduce damage to the second emissive material layer 220 during the preparation of the second barrier material layer 320, and minimize damage to a surface of the second light-emitting structure 221 after the subsequent peeling off and removal of the second barrier portion 321, the second sacrificial portion 421, and the second etch protection portion 451, thereby improving the device performance of the second light-emitting structure 221 and the usage performance of the display panel 10. The second sacrificial material layer 420 is prepared in the same manner as the first sacrificial material layer 410.

In some embodiments, a solubility of the second barrier portion 321 in water is greater than or equal to 10⁻⁴ g/100 mL, which can address the problem of an excessively low solubility of the second barrier portion 321 in water making it difficult to completely remove the second barrier portion 321 during subsequent dissolution and removal of the second barrier portion 321 using an aqueous solvent, resulting in residues remaining on the surface of the second light-emitting structure 221, and thus leading to an increase in voltage and a decrease in lifetime of the second light-emitting structure 221.

In some embodiments, the solubility of the second barrier portion 321 in water ranges from 10⁻⁴ to 10⁻² g/100 mL. For example, the solubility of the second barrier portion 321 in water may be 10⁻⁴ g/100 mL, 3 × 10⁻⁴ g/100 mL, 10⁻³ g/100 mL, or 10⁻² g/100 mL. In the present application, the solubility refers to a solubility at room temperature (20°C).

In these embodiments, the solubility of the second barrier portion 321 in water is greater than or equal to 10⁻⁴ g/100 mL, which can address the problem of an excessively low solubility of the second barrier portion 321 in water making it difficult to completely remove the second barrier portion 321 during subsequent dissolution and removal of the second barrier portion 321 using an aqueous solvent, resulting in residues remaining on the surface of the second light-emitting structure 221, and thus leading to an increase in voltage and a decrease in lifetime of the second light-emitting structure 221. The solubility of the second barrier portion 321 in water is less than or equal to 10⁻² g/100 mL, which can address the problem of an excessively high solubility of the second barrier portion 321 in water causing the solvent in the second sacrificial material layer 420 to tend to completely dissolve the second barrier portion 321 during the preparation of the second sacrificial material layer 420, leading to damage to the second emissive material layer 220 during thermal curing of the second sacrificial material layer 420, or making it difficult to completely remove the second sacrificial material layer 420 subsequently, and thus resulting in residues remaining on the surface of the second light-emitting structure 221.

In some embodiments, a material of the second barrier portion 321 includes an organic material or an inorganic material, and the organic material may include, for example, 8-hydroxyquinoline, etc.

In some embodiments, the inorganic material includes a metal compound, such as calcium fluoride, magnesium fluoride, or lithium fluoride. The metal compound has a relatively low solubility, making it difficult to be dissolved by the solvent of the first sacrificial material layer 410, and allowing subsequent dissolution and removal using an aqueous solvent. The solubility of calcium fluoride in water is 8.575 × 10⁻³ g/100 mL, and the solubility of magnesium fluoride in water is 7.325 × 10⁻³ g/100 mL.

In some embodiments, the second barrier portion 321 has a thickness of 50 Å to 1000 Å. For example, the thickness of the second barrier portion 321 may be 50 Å, 100 Å, 500 Å, or 1000 Å. In the present application, the thickness refers to a dimension in a thickness direction of the display panel 10.

In these embodiments, the thickness of the second barrier portion 321 is greater than or equal to 50 Å, which can address the problem of an excessively small thickness of the second barrier portion 321 causing the solvent in the second sacrificial material layer 420 to tend to completely dissolve the second barrier portion 321 during the preparation of the second sacrificial material layer 420, easily leading to damage to the second emissive material layer 220 during thermal curing of the second sacrificial material layer 420, or making it difficult to completely remove the second sacrificial material layer 420 subsequently, and thus resulting in residues remaining on the surface of the second light-emitting structure 221. The thickness of the second barrier portion 321 is less than or equal to 1000 Å, which can address the problem of an excessively large thickness of the second barrier portion 321 resulting in increased material cost and greater difficulty in subsequent dissolution and removal of the second barrier portion 321, resulting in residues remaining.

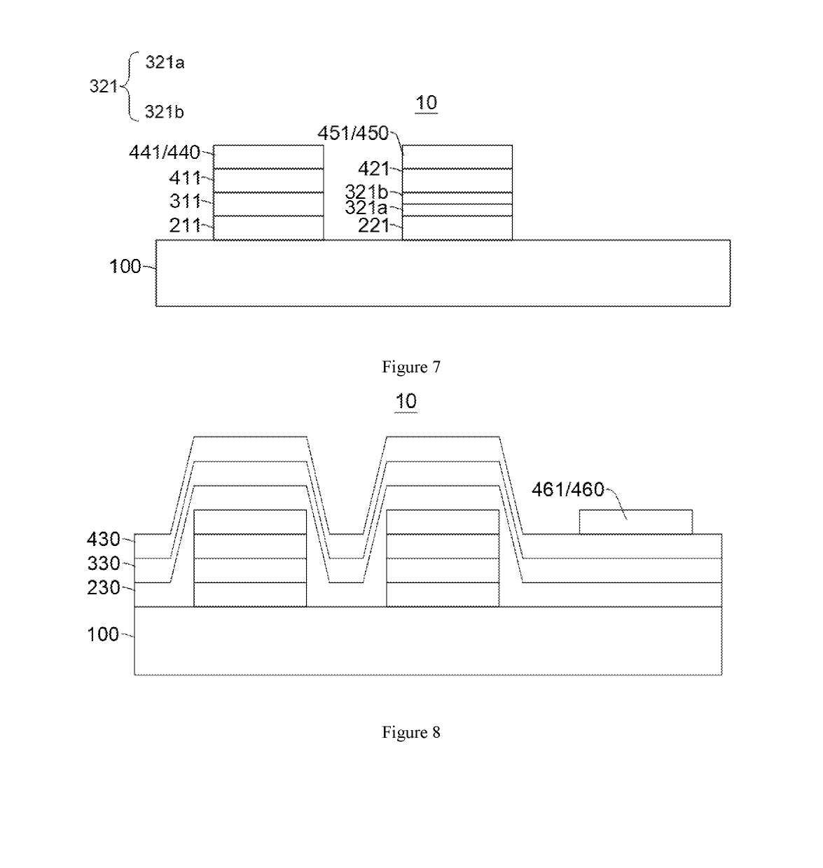

As shown in FIGS. 5 and 7, in some embodiments, the second barrier material layer 320 includes a third material layer and a fourth material layer, and preparing the second barrier material layer 320 on the side of the second emissive material layer 220 facing away from the substrate 100 by means of vacuum evaporation deposition includes: sequentially preparing the third material layer and the fourth material layer on the side of the second emissive material layer 220 facing away from the substrate 100.

In some embodiments, patterning the second emissive material layer 220, the second barrier material layer 320, and the second sacrificial material layer 420 includes: patterning the third material layer and the fourth material layer to form the second barrier portion 321, where the second barrier portion 321 includes a third sub-layer 321aand a fourth sub-layer 321b, and the fourth sub-layer 321bis located on a side of the third sub-layer 321afacing away from the substrate 100.

In these embodiments, the second barrier material layer 320 is prepared in two steps as the third material layer and the fourth material layer, and the third material layer and the fourth material layer form the third sub-layer 321aand the fourth sub-layer 321b, respectively, and solubilities of the third sub-layer 321aand the fourth sub-layer 321bcan be individually controlled, thereby facilitating the separation of the second sacrificial portion 421 from the second light-emitting structure 221 and enabling easy subsequent dissolution and removal.

In some embodiments, the solubility of the fourth sub-layer 321bin water is lower than the solubility of the third sub-layer 321a in water.

In these embodiments, the fourth sub-layer 321bhas a lower solubility in water, and during the preparation of the second sacrificial material layer 420, the solvent of the second sacrificial material layer 420 is difficult to completely dissolve the fourth sub-layer 321b, thereby achieving separation of the second sacrificial portion 421 from the second light-emitting structure 221. The third sub-layer 321ahas a higher solubility in water, and during subsequent dissolution and removal of the second barrier portion 321 using an aqueous solvent, the third sub-layer 321ais easy to be completely dissolved by the water, thereby achieving peeling off of the third sub-layer 321aand the fourth sub-layer 321b.

In some embodiments, the solubility of the fourth sub-layer 321bin water ranges from 10⁻⁴ to 10⁻² g/100 mL. For example, the solubility of the fourth sub-layer 321bin water may be 10⁻⁴ g/100 mL, 3 × 10⁻⁴ g/100 mL, 10⁻³ g/100 mL, or 10⁻² g/100 mL. The fourth sub-layer 321bhas a relatively low solubility in water, and during the preparation of the second sacrificial material layer 420, the solvent of the second sacrificial material layer 420 is difficult to completely dissolve the fourth sub-layer 321b, thereby achieving separation of the second sacrificial portion 421 from the second light-emitting structure 221.

In some embodiments, the solubility of the fourth sub-layer 321b in water is less than or equal to 10⁻⁴ g/100 mL. For example, the solubility of the fourth sub-layer 321bin water may be 10⁻⁷ g/100 mL, 10⁻⁶ g/100 mL, 10⁻⁵ g/100 mL, or 10⁻⁴ g/100 mL, etc. The fourth sub-layer 321b has a relatively low solubility in water, and during the preparation of the second sacrificial material layer 420, the solvent of the second sacrificial material layer 420 is difficult to completely dissolve the fourth sub-layer 321b, thereby achieving separation of the second sacrificial portion 421 from the second light-emitting structure 221.

In some embodiments, the solubility of the third sub-layer 321ain water is greater than or equal to 0.1 g/100 mL. For example, the solubility of the third sub-layer 321a in water is 0.1 g/100 mL, 0.27 g/100 mL, 1 g/100 mL, or 2 g/100 mL. The third sub-layer 321ahas a relatively high solubility in water, and during subsequent dissolution and removal of the second barrier portion 321 using an aqueous solvent, the third sub-layer 321ais easy to be completely dissolved by the water, thereby achieving peeling off of the third sub-layer 321aand the fourth sub-layer 321b.

In some embodiments, a material of the fourth sub-layer 321b includes an inorganic material, such as calcium fluoride, magnesium fluoride, or a cathode material, or an organic material, such as a hole blocking material or an electron transport material, all of which have relatively low solubility.

In some embodiments, a material of the third sub-layer 321a includes an organic material or an inorganic material, such as lithium fluoride or 8-hydroxyquinoline, all of which have relatively high solubility.

In some embodiments, a thickness of the fourth sub-layer 321b is less than a thickness of the third sub-layer 321a.

In these embodiments, the fourth sub-layer 321b has a smaller thickness, which reduces material costs and facilitates easier peeling off of the fourth sub-layer 321bduring subsequent dissolution of the third sub-layer 321ausing an aqueous solvent. The third sub-layer 321ahas a larger thickness, which can more effectively separate the second emissive material layer 220 from the second sacrificial material layer 420, and avoid the problem of an excessively small thickness of the third sub-layer 321aresulting in partial adhesion of the fourth sub-layer 321bto the surface of the second light-emitting structure 221 after dissolution and removal of the third sub-layer 321ausing an aqueous solvent, making it difficult to completely peel off the fourth sub-layer.

In some embodiments, the thickness of the third sub-layer 321aranges from 50 Å to 1000 Å. For example, the thickness of the third sub-layer 321a may be 50 Å, 100 Å, 500 Å, or 1000 Å, etc.

In these embodiments, the thickness of the third sub-layer 321a is greater than or equal to 50 Å, which can address the problem of an excessively small thickness of the third sub-layer 321aresulting in partial adhesion of the fourth sub-layer 321bto the surface of the third light-emitting structure 231 after dissolution and removal of the third sub-layer 321ausing an aqueous solvent, making it difficult to completely peel off the fourth sub-layer. The thickness of the third sub-layer 321a is less than or equal to 1000 Å, which can address the problem of an excessively large thickness of the third sub-layer 321a resulting in increased material cost and greater difficulty in subsequent dissolution and removal of the third sub-layer 321a, resulting in residues remaining.

In some embodiments, the thickness of the fourth sub-layer 321b ranges from 2 Å to 50 Å. For example, the thickness of the fourth sub-layer 321b may be 2 Å, 10 Å, 20 Å, or 50 Å, etc.

In these embodiments, the thickness of the fourth sub-layer 321b is greater than or equal to 2 Å, which can address the problem of an excessively small thickness of the fourth sub-layer 321bresulting in greater difficulty in the preparation process of the fourth sub-layer 321band making the fourth sub-layer 321b prone to being completely dissolved by the solvent of the second sacrificial material layer 420, thereby further dissolving the third sub-layer 321a. This may lead to damage to the second emissive material layer 220 during thermal curing of the second sacrificial material layer 420, or make it difficult to completely remove the second sacrificial material layer 420 subsequently, resulting in residues remaining on the surface of the second light-emitting structure 221.

As shown in FIGS. 8 to 10, in some embodiments, the method further includes, posterior to patterning the second emissive material layer 220, the second barrier material layer 320, and the second sacrificial material layer 420 to form the second light-emitting structure 221, the second barrier portion 321, and the second sacrificial portion 421,
preparing a third emissive material layer 230 on the substrate 100;
preparing a third barrier material layer 330 on a side of the third emissive material layer 230 facing away from the substrate 100 by means of vacuum evaporation deposition;
preparing a third sacrificial material layer 430 on a side of the third barrier material layer 330 facing away from the substrate 100;
preparing a third etch protection layer 460 on a side of the third sacrificial material layer 430 facing away from the substrate 100, where the third etch protection layer 460 includes a plurality of spaced-apart third etch protection portions 461; and
patterning the third emissive material layer 230, the third barrier material layer 330, and the third sacrificial material layer 430 to form a third light-emitting structure 231, a third barrier portion 331, and a third sacrificial portion 431 in a region corresponding to each third etch protection portion 461.

In these embodiments, after forming the second light-emitting structure 221, the second barrier portion 321, and the second sacrificial portion 421, sequentially preparing the third emissive material layer 230 and the third barrier material layer 330 on the substrate 100, and then the third sacrificial material layer 430 on the side of the third barrier material layer 330 facing away from the substrate 100. enables the third barrier material layer 330 to separate the third emissive material layer 230 from the third sacrificial material layer 430, thereby avoiding damage to the third emissive material layer 230 during the preparation of the third sacrificial material layer 430. Continuously preparing on the third sacrificial material layer 430 the third etch protection layer 460 including a plurality of third etch protection portions 461 enables the plurality of third etch protection portions 461 to provide etch protection for the third emissive material layer 230, the third barrier material layer 330, and the third sacrificial material layer 430, and the third emissive material layer 230, the third barrier material layer 330, and the third sacrificial material layer 430 are retained in the region where each third etch protection portions 461 is located, and parts thereof in other regions are etched away, thereby forming the third light-emitting structure 231, the third barrier portion 331, and the third sacrificial portion 431. The third barrier material layer 330 being formed by means of vacuum evaporation deposition can reduce damage to the third emissive material layer 230 during the preparation of the third barrier material layer 330, and minimize damage to a surface of the third light-emitting structure 231 after the subsequent peeling off and removal of the third barrier portion 331, the third sacrificial portion 431, and the third etch protection portion 461, thereby improving the device performance of the third light-emitting structure 231 and the usage performance of the display panel 10. The third sacrificial material layer 430 is prepared in the same manner as the first sacrificial material layer 410.

In some embodiments, a solubility of the third barrier portion 331 in water is greater than or equal to 10⁻⁴ g/100 mL, which can address the problem of an excessively low solubility of the third barrier portion 331 in water making it difficult to completely remove the third barrier portion 331 during subsequent dissolution and removal of the third barrier portion 331 using an aqueous solvent, resulting in residues remaining on the surface of the third light-emitting structure 231, and thus leading to an increase in voltage and a decrease in lifetime of the third light-emitting structure 231.

In some embodiments, the solubility of the third barrier portion 331 in water ranges from 10⁻⁴ to 10⁻² g/100 mL. For example, the solubility of the third barrier portion 331 in water may be 10⁻⁴ g/100 mL, 3 × 10⁻⁴ g/100 mL, 10⁻³ g/100 mL, or 10⁻² g/100 mL. In the present application, the solubility refers to a solubility at room temperature (20°C).

In these embodiments, the solubility of the third barrier portion 331 in water is greater than or equal to 10⁻⁴ g/100 mL, which can address the problem of an excessively low solubility of the third barrier portion 331 in water making it difficult to completely remove the third barrier portion 331 during subsequent dissolution and removal of the third barrier portion 331 using an aqueous solvent, resulting in residues remaining on the surface of the third light-emitting structure 231, and thus leading to an increase in voltage and a decrease in lifetime of the third light-emitting structure 231. The solubility of the third barrier portion 331 in water is less than or equal to 10⁻² g/100 mL, which can address the problem of an excessively high solubility of the third barrier portion 331 in water causing the solvent in the third sacrificial material layer 430 to tend to completely dissolve the third barrier portion 331 during the preparation of the third sacrificial material layer 430, leading to damage to the third emissive material layer 230 during thermal curing of the third sacrificial material layer 430, or making it difficult to completely remove the third sacrificial material layer 430 subsequently, and thus resulting in residues remaining on the surface of the third light-emitting structure 231.

In some embodiments, a material of the third barrier portion 331 includes an organic material or an inorganic material, and the organic material may include, for example, 8-hydroxyquinoline, etc.

In some embodiments, the inorganic material includes a metal compound, such as calcium fluoride, magnesium fluoride, or lithium fluoride. The metal compound has a relatively low solubility, making it difficult to be dissolved by the solvent of the first sacrificial material layer 410, and allowing subsequent dissolution and removal using an aqueous solvent. The solubility of calcium fluoride in water is 8.575 × 10⁻³ g/100 mL, and the solubility of magnesium fluoride in water is 7.325 × 10⁻³ g/100 mL.

In some embodiments, the third barrier portion 331 has a thickness of 50 Å to 1000 Å. For example, the thickness of the third barrier portion 331 may be 50 Å, 100 Å, 500 Å, or 1000 Å. In the present application, the thickness refers to a dimension in a thickness direction of the display panel 10.

In these embodiments, the thickness of the third barrier portion 331 is greater than or equal to 50 Å, which can address the problem of an excessively small thickness of the third barrier portion 331 causing the solvent in the third sacrificial material layer 430 to tend to completely dissolve the third barrier portion 331 during the preparation of the third sacrificial material layer 430, leading to damage to the third emissive material layer 230 during thermal curing of the third sacrificial material layer 430, or making it difficult to completely remove the third sacrificial material layer 430 subsequently, and thus resulting in residues remaining on the surface of the third light-emitting structure 231. The thickness of the third barrier portion 331 is less than or equal to 1000 Å, which can address the problem of an excessively large thickness of the third barrier portion 331 resulting in increased material cost and greater difficulty in subsequent dissolution and removal of the third barrier portion 331, resulting in residues remaining.

As shown in FIGS. 8 and 10, in some embodiments, the third barrier material layer 330 includes a fifth material layer and a sixth material layer, and preparing the third barrier material layer 330 on the side of the third emissive material layer 230 facing away from the substrate 100 by means of vacuum evaporation deposition includes:
sequentially preparing the fifth material layer and the sixth material layer on the side of the third emissive material layer 230 facing away from the substrate 100.

In some embodiments, patterning the third emissive material layer 230, the third barrier material layer 330, and the third sacrificial material layer 430 includes:
patterning the fifth material layer and the sixth material layer to form the third barrier portion 331, where the third barrier portion 331 includes a fifth sub-layer 331a and a sixth sub-layer 331b, and the sixth sub-layer 331b is located on a side of the fifth sub-layer 331a facing away from the substrate 100.

In these embodiments, the third barrier material layer 330 is prepared in two steps as the fifth material layer and the sixth material layer, and the fifth material layer and the sixth material layer form the fifth sub-layer 331aand the sixth sub-layer 331b, respectively, and solubilities of the fifth sub-layer 331a and the sixth sub-layer 331bcan be individually controlled, thereby facilitating the separation of the third sacrificial portion 431 from the third light-emitting structure 231 and enabling easy subsequent dissolution and removal.

In some embodiments, the solubility of the sixth sub-layer 331bin water is lower than the solubility of the fifth sub-layer 331ain water.

In these embodiments, the sixth sub-layer 331b has a lower solubility in water, and during the preparation of the third sacrificial material layer 430, the solvent of the third sacrificial material layer 430 is difficult to completely dissolve the sixth sub-layer 331b, thereby achieving separation of the third sacrificial portion 431 from the third light-emitting structure 231. The fifth sub-layer 331ahas a higher solubility in water, and during subsequent dissolution and removal of the third barrier portion 331 using an aqueous solvent, the fifth sub-layer 331ais easy to be completely dissolved by the water, thereby achieving peeling off of the fifth sub-layer 331aand the sixth sub-layer 331b.

In some embodiments, the solubility of the sixth sub-layer 331b in water ranges from 10⁻⁴ to 10⁻² g/100 mL. For example, the solubility of the sixth sub-layer 331bin water may be 10⁻⁴ g/100 mL, 3 × 10⁻⁴ g/100 mL, 10⁻³ g/100 mL, or 10⁻² g/100 mL. The sixth sub-layer 331b has a relatively low solubility in water, and during the preparation of the third sacrificial material layer 430, the solvent of the third sacrificial material layer 430 is difficult to completely dissolve the sixth sub-layer 331b, thereby achieving separation of the third sacrificial portion 431 from the third light-emitting structure 231.

In some embodiments, the solubility of the sixth sub-layer 331b in water is less than or equal to 10⁻⁴ g/100 mL. For example, the solubility of the sixth sub-layer 331bin water may be 10⁻⁷ g/100 mL, 10⁻⁶ g/100 mL, 10⁻⁵ g/100 mL, or 10⁻⁴ g/100 mL, etc. The sixth sub-layer 331b has a relatively low solubility in water, and during the preparation of the third sacrificial material layer 430, the solvent of the third sacrificial material layer 430 is difficult to completely dissolve the sixth sub-layer 331b, thereby achieving separation of the third sacrificial portion 431 from the third light-emitting structure 231.

In some embodiments, the solubility of the fifth sub-layer 331a in water is greater than or equal to 0.1 g/100 mL. For example, the solubility of the fifth sub-layer 331a in water is 0.1 g/100 mL, 0.27 g/100 mL, 1 g/100 mL, or 2 g/100 mL. The fifth sub-layer 331a has a relatively high solubility in water, and during subsequent dissolution and removal of the third barrier portion 331 using an aqueous solvent, the fifth sub-layer 331a is easy to be completely dissolved by the water, thereby achieving peeling off of the fifth sub-layer 331a and the sixth sub-layer 331b.

In some embodiments, a material of the sixth sub-layer 331b includes an inorganic material, such as calcium fluoride, magnesium fluoride, or a cathode material, or an organic material, such as a hole blocking material or an electron transport material, all of which have relatively low solubility.

In some embodiments, a material of the fifth sub-layer 331aincludes an organic material or an inorganic material, such as lithium fluoride or 8-hydroxyquinoline, all of which have relatively high solubility.

In some embodiments, a thickness of the sixth sub-layer 331b is less than a thickness of the fifth sub-layer 331a.

In these embodiments, the sixth sub-layer 331bhas a smaller thickness, which reduces material costs and facilitates easier peeling off of the sixth sub-layer 331bduring subsequent dissolution of the fifth sub-layer 331ausing an aqueous solvent. The fifth sub-layer 331ahas a larger thickness, which can more effectively separate the third emissive material layer 230 from the third sacrificial material layer 430, and avoid the problem of an excessively small thickness of the fifth sub-layer 331a resulting in partial adhesion of the sixth sub-layer 331bto the surface of the third light-emitting structure 231 after dissolution and removal of the fifth sub-layer 331ausing an aqueous solvent, making it difficult to completely peel off the sixth sub-layer.

In some embodiments, the thickness of the fifth sub-layer 331a ranges from 50 Å to 1000 Å. For example, the thickness of the fifth sub-layer 331a may be 50 Å, 100 Å, 500 Å, or 1000 Å, etc.

In these embodiments, the thickness of the fifth sub-layer 331a is greater than or equal to 50 Å, which can address the problem of an excessively small thickness of the fifth sub-layer 331a resulting in partial adhesion of the sixth sub-layer 331b to the surface

of the third light-emitting structure 231 after dissolution and removal of the fifth sub-layer 331a using an aqueous solvent, making it difficult to completely peel off the sixth sub-layer. The thickness of the fifth sub-layer 331ais less than or equal to 1000 Å, which can address the problem of an excessively large thickness of the fifth sub-layer 331a resulting in increased material cost and greater difficulty in subsequent dissolution and removal of the fifth sub-layer 331a, resulting in residues remaining.

In some embodiments, the thickness of the sixth sub-layer 331branges from 2 Å to 50 Å. For example, the thickness of the sixth sub-layer 331b may be 2 Å, 10 Å, 20 Å, or 50 Å, etc.

In these embodiments, the thickness of the sixth sub-layer 331b is greater than or equal to 2 Å, which can address the problem of an excessively small thickness of the sixth sub-layer 331b resulting in greater difficulty in the preparation process of the sixth sub-layer 331b and making the sixth sub-layer 331b prone to being completely dissolved by the solvent of the third sacrificial material layer 430, thereby further dissolving the fifth sub-layer 331a. This may lead to damage to the third emissive material layer 230 during thermal curing of the third sacrificial material layer 430, or make it difficult to completely remove the third sacrificial material layer 430 subsequently, resulting in residues remaining on the surface of the third light-emitting structure 231.

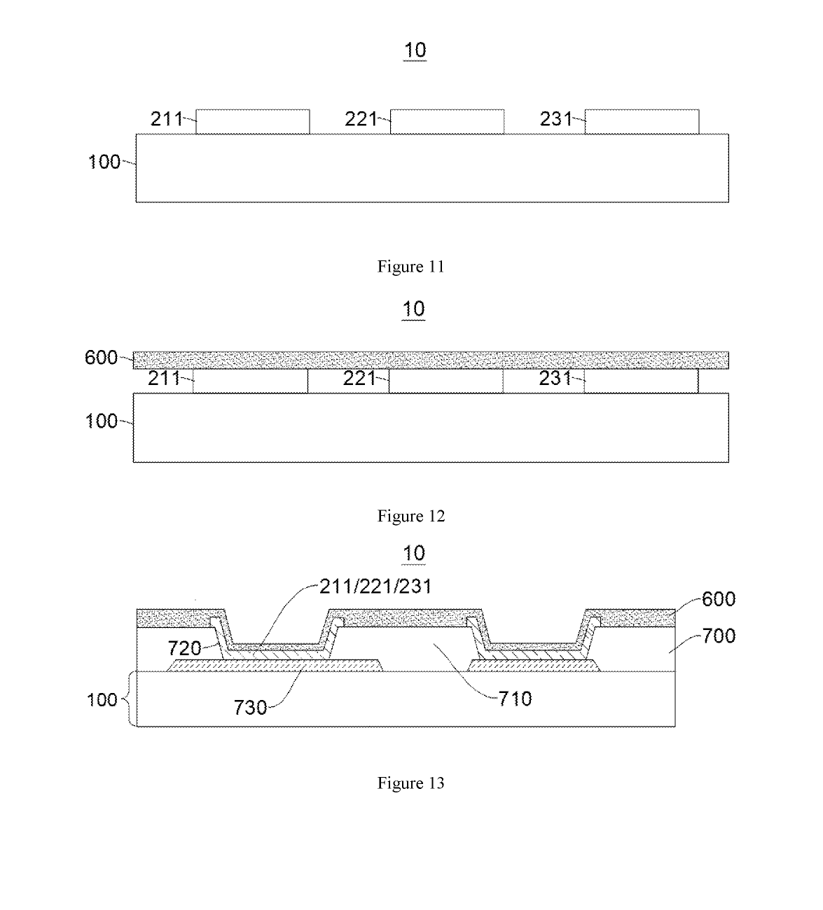

As shown in FIG. 11, in some embodiments, the method further includes, posterior to patterning the third emissive material layer 230, the third barrier material layer 330, and the third sacrificial material layer 430 to form the third light-emitting structure 231, the third barrier portion 331, and the third sacrificial portion 431 in the region corresponding to each third etch protection portion 461,
removing the first etch protection portion 441, the second etch protection portion 451, and the third etch protection portion 461;
removing the first sacrificial portion 411, the second sacrificial portion 421, and the third sacrificial portion 431; and
removing the first barrier portion 311, the second barrier portion 321, and the third barrier portion 331.

In these embodiments, after forming the third light-emitting structure 231, the third barrier portion 331, and the third sacrificial portion 431 in the region corresponding to each third etch protection portion 461, removing the first etch protection portion 441, the second etch protection portion 451, the third etch protection portion 461, the first sacrificial portion 411, the second sacrificial portion 421, the third sacrificial portion 431, the first barrier portion 311, the second barrier portion 321, and the third barrier portion 331 facilitates the subsequent preparation of an electron transport layer, an electron injection layer, and a first electrode layer 600 on the first light-emitting structure 211, the second light-emitting structure 221, and the third light-emitting structure 231 to enable the light emission of the first light-emitting structure 211, the second light-emitting structure 221, and the third light-emitting structure 231.

In some embodiments, removing the first sacrificial portion 411, the second sacrificial portion 421, and the third sacrificial portion 431 includes:
dissolving and removing the first sacrificial portion 411, the second sacrificial portion 421, and the third sacrificial portion 431 using a solvent.

In these embodiments, using the solvent (e.g., water) to dissolve and remove the first sacrificial portion 411, the second sacrificial portion 421, and the third sacrificial portion 431 facilitates the subsequent preparation of the electron transport layer, the electron injection layer, and the first electrode layer 600 on the first light-emitting structure 211, the second light-emitting structure 221, and the third light-emitting structure 231 to enable the light emission of the first light-emitting structure 211, the second light-emitting structure 221, and the third light-emitting structure 231.

In some embodiments, removing the first barrier portion 311, the second barrier portion 321, and the third barrier portion 331 includes:
dissolving and removing the first barrier portion 311, the second barrier portion 321, and the third barrier portion 331 using a solvent.

In these embodiments, using the solvent (e.g., water) to dissolve and remove the first sacrificial portion 411, the second sacrificial portion 421, and the third sacrificial portion 431 can also dissolve and remove the first barrier portion 311, the second barrier

portion 321, and the third barrier portion 331, thereby simplifying the preparation process.

In some embodiments, the first barrier portion 311 includes a first sub-layer 311a and a second sub-layer 311b, and dissolving and removing the first barrier portion 311, the second barrier portion 321, and the third barrier portion 331 using the solvent includes:
dissolving and removing the first sub-layer 311ausing the solvent to peel off the second sub-layer 311b.

In these embodiments, since the solubility of the first sub-layer 311ais higher than the solubility of the second sub-layer 311b, the first sub-layer 311a can be fully dissolved using the solvent (e.g., water). Once the first sub-layer 311a between the second sub-layer 311b and the first light-emitting structure 211 is dissolved, the second sub-layer 311bnaturally peels off from the first light-emitting structure 211.

In some embodiments, the second barrier portion 321 includes a third sub-layer 321aand a fourth sub-layer 321b, and dissolving and removing the first barrier portion 311, the second barrier portion 321, and the third barrier portion 331 using the solvent includes:
dissolving and removing the third sub-layer 321ausing the solvent to peel off the fourth sub-layer 321b.

In these embodiments, since the solubility of the third sub-layer 321a is higher than the solubility of the fourth sub-layer 321b, the third sub-layer 321acan be fully dissolved using the solvent (e.g., water). Once the third sub-layer 321a between the fourth sub-layer 321band the second light-emitting structure 221 is dissolved, the fourth sub-layer 321bnaturally peels off from the second light-emitting structure 221.

In some embodiments, the third barrier portion 331 includes a fifth sub-layer 331aand a sixth sub-layer 331b, and dissolving and removing the first barrier portion 311, the second barrier portion 321, and the third barrier portion 331 using the solvent includes:
dissolving and removing the fifth sub-layer 331a using the solvent to peel off the sixth sub-layer 331b.

In these embodiments, since the solubility of the fifth sub-layer 331a is higher than the solubility of the sixth sub-layer 331b, the fifth sub-layer 331acan be fully dissolved using the solvent (e.g., water). Once the fifth sub-layer 331a between the sixth sub-layer 331b and the third light-emitting structure 231 is dissolved, the sixth sub-layer 331b naturally peels off from the third light-emitting structure 231.

As shown in FIG. 12, in some embodiments, the method further includes, posterior to removing the first barrier portion 311, the second barrier portion 321, and the third barrier portion 331,
sequentially preparing a first carrier layer (not shown) and a first electrode layer 600 on the substrate 100.

In some embodiments, the first carrier layer includes an electron transport layer and an electron injection layer.

In these embodiments, preparing the first carrier layer (electron transport layer and electron injection layer) and the first electrode layer 600 on the first light-emitting structure 211, the second light-emitting structure 221, and the third light-emitting structure 231 enables the light emission of the first light-emitting structure 211, the second light-emitting structure 221, and the third light-emitting structure 231.

In some embodiments, the method further includes, posterior to sequentially preparing the first carrier layer and the first electrode layer 600 on the substrate 100,
preparing a first encapsulation layer (not shown) on a side of the first electrode layer 600 facing away from the substrate 100.

In some embodiments, a material of the first encapsulation layer includes an inorganic material.

In some embodiments, the method further includes, prior to preparing the first barrier material layer 310 on the side of the first emissive material layer 210 facing away from the substrate 100 by means of vacuum evaporation deposition,
preparing a second carrier layer on the side of the first emissive material layer 210 facing away from the substrate 100.

In some embodiments, the second carrier layer includes a first hole blocking material layer.

In some embodiments, the method further includes, prior to preparing the second barrier material layer 320 on the side of the second emissive material layer 220 facing away from the substrate 100 by means of vacuum evaporation deposition,
preparing a third carrier layer on the side of the second emissive material layer 220 facing away from the substrate 100.

In some embodiments, the third carrier layer includes a second hole blocking material layer.

In some embodiments, the method further includes, prior to preparing the third barrier material layer 330 on the side of the third emissive material layer 230 facing away from the substrate 100 by means of vacuum evaporation deposition,
preparing a fourth carrier layer on the side of the third emissive material layer 230 facing away from the substrate 100.

In some embodiments, the fourth carrier layer includes a third hole blocking material layer.

In some embodiments, the method further includes, prior to step S01,
preparing a hole injection layer (not shown), a hole transport layer (not shown), and an electron blocking layer (not shown) on the substrate 100.

As shown in FIGS. 1 to 10, In some embodiments, each of the first barrier portion 311, the second barrier portion 321, and the third barrier portion 331 is of a single-layer structure, and the first barrier portion 311, the second barrier portion 321, and the third barrier portion 331 can be prepared using the same process, thereby simplifying the preparation process. In some embodiments, when the first barrier portion 311 is of a single-layer structure, the second barrier portion 321 and the third barrier portion 331 may each be of a single-layer structure or a double-layer structure.

In some embodiments, the first barrier portion 311 includes a first sub-layer 311a and a second sub-layer 311b, the second barrier portion 321 includes a third sub-layer 321aand a fourth sub-layer 321b, and the third barrier portion 331 includes a fifth sub-layer 331aand a sixth sub-layer 331b. Each of the first barrier portion 311, the second barrier portion 321, and the third barrier portion 331 is of a double-layer structure, and the first barrier portion 311, the second barrier portion 321, and the third barrier portion 331 can be prepared using the same process, thereby simplifying the preparation process. In some embodiments, when the first barrier portion 311 is of a double-layer structure, the second barrier portion 321 and the third barrier portion 331 may each be of a single-layer structure or a double-layer structure.

Referring to FIG. 13, FIG. 13 is a partial cross-sectional view of a display panel according to an embodiment of the present application.

As shown in FIG. 13, In some embodiments, the method further includes, prior to step S01,
sequentially preparing second electrodes 730 and a pixel define layer 700 on the substrate 100, where the pixel define layer 700 includes pixel defining portions 710 and pixel openings 720 enclosed by the pixel defining portions 710, and at least part of each second electrode 730 is exposed through a pixel opening 720.

In these embodiments, the pixel defining portions 710 of the pixel define layer 700 enclose the pixel openings 720 to dispose first light-emitting structures 211, second light-emitting structures 221, and third light-emitting structures 231, and the first light-emitting structures 211, the second light-emitting structures 221, and the third light-emitting structures 231 are located within different pixel openings 720. In addition, the pixel defining portions 710 define the placement regions of the light-emitting structures, thereby reducing color crosstalk between the light-emitting structures.

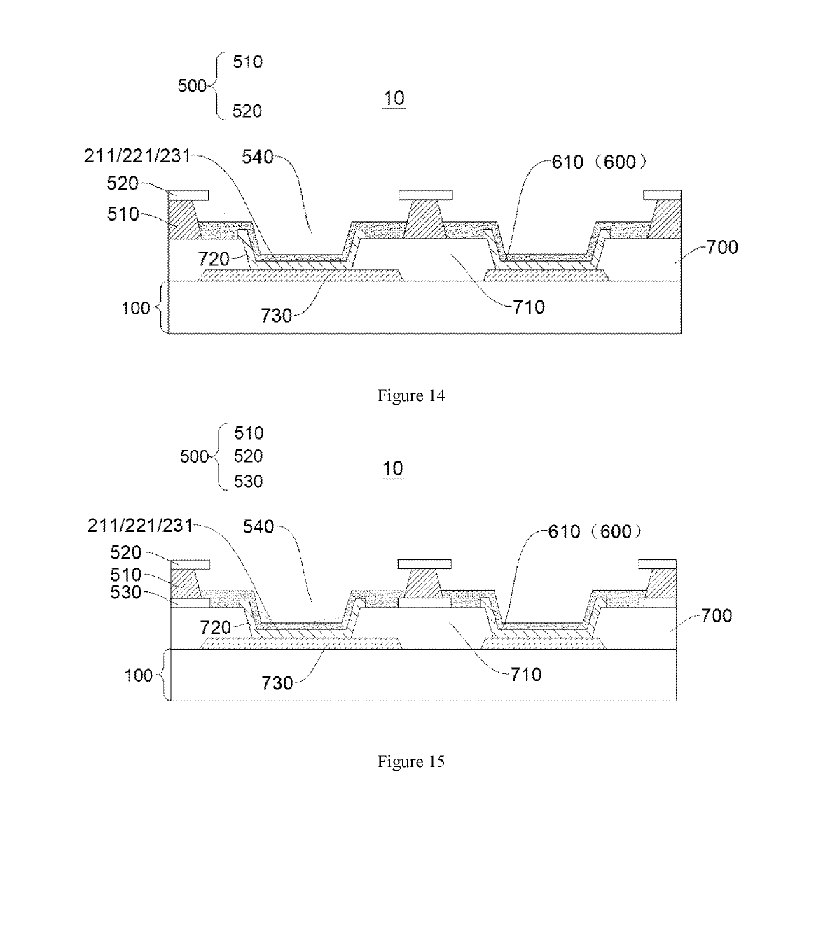

Referring to FIG. 14, FIG. 14 is a partial cross-sectional view of a display panel according to another embodiment.

As shown in FIG. 14, In some embodiments, the fabrication method further includes, prior to step S01,
preparing an isolation structure 500 on the substrate 100, where the isolation structure 500 encloses a plurality of isolation openings 540.

In some embodiments, the first light-emitting structures 211, the second light-emitting structures 221, and the third light-emitting structures 231 are located within different isolation openings 540.

In these embodiments, the isolation structure 500 is disposed between adjacent light-emitting structures to reduce mutual interference therebetween. In some embodiments, the isolation structure 500 may serve as a partition to partition the emissive material layer, thereby forming light-emitting structures within the isolation openings 540.

In some embodiments, the first electrode layer 600 includes a plurality of first electrodes 610 located within the plurality of isolation openings 540. The first electrodes 610 are electrically connected to the isolation structure 500, and the spaced-apart first electrodes 610 are electrically connected via the isolation structure 500 to form a full-area electrode, thereby ensuring normal light emission of the light-emitting structures.

One of a first electrode 610 and a second electrode 730 serves as an anode of a light-emitting structure, and the other one serves as a cathode of the light-emitting structure. In the embodiments of the present application, the first electrode 610 is exemplified as the cathode of the light-emitting structure, and the second electrode 730 as the anode of the light-emitting structure.

In some embodiments, a material of the pixel defining portion 710 includes an inorganic material or an organic material.

In some embodiments, the isolation structure 500 includes a first layer 510 and a second layer 520 located on a side of the first layer 510 facing away from the substrate 100, an orthographic projection of the first layer 510 on the substrate 100 being located within an orthographic projection of the second layer 520 on the substrate 100.

In these embodiments, the isolation structure 500 includes the first layer 510 and the second layer 520 on the side of the first layer 510 facing away from the substrate 100,
the first layer 510 and the second layer 520 are stacked to form the isolation structure 500, the orthographic projection of the first layer 510 disposed close to the substrate 100 on the substrate 100 is located within the orthographic projection of the second layer 520 on the substrate 100, the second layer 520 has a larger area than the first layer 510, and the second layer 520 covers a surface of the first layer 510 close to the second layer 520, in which case the first layer 510 is recessed with respect to the second layer 520 in a direction away from an isolation opening 540. During the preparation of the emissive material layer, for the emissive material layer, a significant height difference is formed at edges of the isolation structure 500, and the first layer 510 is recessed relative to the second layer 520, making it difficult for the emissive material layer to connect at the edges of the isolation structure 500. As a result, the emissive material layer fractures, forming mutually disconnected light-emitting structures. This allows the light-emitting structures to be prepared without using a fine metal mask (FMM), thereby reducing the development and use of FMM and lowering preparation costs.

In some embodiments, the first layer 510 includes a conductive material. For example, the first layer 510 includes a non-metallic conductive material or a metallic conductive material.

In some embodiments, the second layer 520 includes a conductive material or an insulation material.

In these embodiments, the second layer 520 includes a conductive material. For example, the second layer 520 includes a non-metallic conductive material or a metallic conductive material. When the second layer 520 is made of a non-metallic conductive material or an insulation material, during wet etching of the first layer 510 with an etching solution, the second layer 520 is difficult to etch, thereby making it easier for the first layer 510 to be recessed relative to the second layer 520.

In some embodiments, the first layer 510 and the second layer 520 each include a metallic material, and the first layer 510 and the second layer 520 are made of different materials.

In these embodiments, when the first layer 510 and the second layer 520 are each made of the metallic material, the first layer 510 may be wet etched with an etching solution, and the etching solution is provided to enable an etching rate of the second layer

520 to be lower than an etching rate of the first layer 510. Since the first layer 510 has a higher etching rate, when wet etching is performed with the etching solution, the first layer 510 is etched faster even though the second layer 520 is subjected to some etching, which causes the first layer 510 to be recessed relative to the second layer 520.

Referring to FIG. 15, FIG. 15 is a partial cross-sectional view of a display panel according to yet another embodiment.

As shown in FIG. 15, in some embodiments, the isolation structure 500 further includes a third layer 530 located on a side of the first layer 510 facing the substrate 100, the orthographic projection of the first layer 510 on the substrate 100 being located within an orthographic projection of the third layer 530 on the substrate 100.

In these embodiments, to obtain the recessed first layer 510, the first layer 510 has a higher etching rate than the second layer 520 and the third layer 530 during etching, forming the recessed first layer 510. Since the etching rate of the first layer 510 is higher, more waste is generated during the etching and is likely to enter other locations of the display panel 10, thus causing an adverse effect. After the third layer 530 is provided, the first layer 510 may be better adhered to the third layer 530, and the generated etching waste falls on the third layer 530 to facilitate removal.

The embodiments of the present application further provide a display panel 10 fabricated by the fabrication method of any one of the above embodiments. Since the display panel 10 according to the embodiments of the present application is fabricated by the fabrication method of any one of the above embodiments, the display panel 10 according to the embodiments of the present application has the beneficial effects of the fabrication method of any one of the above embodiments, and will not be described in detail herein.

Embodiments of the present application further provide a display device, including a display panel 10 of any one of the above embodiments, or a display panel 10 fabricated by the fabrication method of any one of the above embodiments. Since the display device according to the embodiments of the present application includes the display panel 10 of any one of the above embodiments, or the display panel 10 fabricated by the fabrication method of any one of the above embodiments, the display device according to the embodiments of the present application has the beneficial effects of the display panel 10 of any one of the above embodiments or of the display panel 10 fabricated by the fabrication method of any one of the above embodiments, and will not be described in detail herein.

The display device in the embodiments of the present application includes, but is not limited to, devices having a display function, such as a mobile phone, a personal digital assistant (PDA), a tablet computer, an e-book reader, a television, an access control system, a smart fixed-line telephone, or a console.

The embodiments of the present application as described above neither set forth all the details, nor do they limit the present application to only the described specific embodiments. Apparently, many modifications and variations can be made in light of the above description. The embodiments are selected and described in this specification to better explain the principles and practical applications of the present application, and good use of the present application can be made and modify and use the present application. The present application is limited only by the claims and all the scopes and equivalents thereof.

What is claimed is:

1. A fabrication method for a display panel, comprising:
preparing a first emissive material layer on a substrate;
preparing a first barrier material layer on a side of the first emissive material layer facing away from the substrate by means of vacuum evaporation deposition;
preparing a first sacrificial material layer on a side of the first barrier material layer facing away from the substrate;
preparing a first etch protection layer on a side of the first sacrificial material layer facing away from the substrate, wherein the first etch protection layer comprises a plurality of spaced-apart first etch protection portions; and
patterning the first emissive material layer, the first barrier material layer, and the first sacrificial material layer to form a first light-emitting structure, a first barrier portion, and a first sacrificial portion in a region corresponding to each first etch protection portion.

2. The fabrication method according to claim 1, wherein a solubility of the first barrier portion in water is greater than or equal to 10⁻⁴ g/100 mL;
the solubility of the first barrier portion in water ranges from 10⁻⁴ to 10⁻² g/100 mL;
a material of the first barrier portion comprises an organic material or an inorganic material;
the inorganic material comprises a metal compound; and
the first barrier portion has a thickness of 50 Å to 1000 Å.

3. The fabrication method according to claim 1, wherein the first barrier material layer comprises a first material layer and a second material layer, and preparing the first barrier material layer on the side of the first emissive material layer facing away from the substrate by means of vacuum evaporation deposition comprises:
sequentially preparing the first material layer and the second material layer on the side of the first emissive material layer facing away from the substrate; and
patterning the first emissive material layer, the first barrier material layer, and the first sacrificial material layer comprises:
patterning the first material layer and the second material layer to form the first barrier portion, wherein the first barrier portion comprises a first sub-layer and a second sub-layer, and the second sub-layer is located on a side of the first sub-layer facing away from the substrate.

4. The fabrication method according to claim 3, wherein a solubility of the second sub-layer in water is lower than a solubility of the first sub-layer in water;
the solubility of the second sub-layer in water ranges from 10⁻⁴ to 10⁻² g/100 mL;
the solubility of the first sub-layer in water is greater than or equal to 0.1 g/100 mL;
a material of the second sub-layer comprises an inorganic material; and
a material of the first sub-layer comprises an organic material or an inorganic material.

5. The fabrication method according to claim 3, wherein a thickness of the second sub-layer is less than a thickness of the first sub-layer;
the thickness of the first sub-layer ranges from 50 Å to 1000 Å; and
the thickness of the second sub-layer ranges from 2 Å to 50 Å.

6. The fabrication method according to claim 1, further comprising, posterior to patterning the first emissive material layer, the first barrier material layer, and the first sacrificial material layer to form the first light-emitting structure, the first barrier portion, and the first sacrificial portion,
preparing a second emissive material layer on the substrate;
preparing a second barrier material layer on a side of the second emissive material layer facing away from the substrate by means of vacuum evaporation deposition;
preparing a second sacrificial material layer on a side of the second barrier material layer facing away from the substrate;
preparing a second etch protection layer on a side of the second sacrificial material layer facing away from the substrate, wherein the second etch protection layer comprises a plurality of spaced-apart second etch protection portions; and
patterning the second emissive material layer, the second barrier material layer, and the second sacrificial material layer to form a second light-emitting structure, a second barrier portion, and a second sacrificial portion in a region corresponding to each second etch protection portion.

7. The fabrication method according to claim 6, wherein a solubility of the second barrier portion in water is greater than or equal to 10⁻⁴ g/100 mL;
the solubility of the second barrier portion in water ranges from 10⁻⁴ to 10⁻² g/100 mL;
a material of the second barrier portion comprises an organic material or an inorganic material;
the inorganic material comprises a metal compound; and
the second barrier portion has a thickness of 50 Å to 1000 Å.

8. The fabrication method according to claim 6, wherein the second barrier material layer comprises a third material layer and a fourth material layer, and preparing the second barrier material layer on the side of the second emissive material layer facing away from the substrate by means of vacuum evaporation deposition comprises:
sequentially preparing the third material layer and the fourth material layer on the side of the second emissive material layer facing away from the substrate; and
patterning the second emissive material layer, the second barrier material layer, and the second sacrificial material layer comprises:
patterning the third material layer and the fourth material layer to form the second barrier portion, wherein the second barrier portion comprises a third sub-layer and a fourth sub-layer, and the fourth sub-layer is located on a side of the third sub-layer facing away from the substrate.

9. The fabrication method according to claim 8, wherein a solubility of the fourth sub-layer in water is lower than a solubility of the third sub-layer in water;
the solubility of the fourth sub-layer in water ranges from 10⁻⁴ to 10⁻² g/100 mL;
the solubility of the third sub-layer in water is greater than or equal to 0.1 g/100 mL;
a material of the fourth sub-layer comprises an inorganic material; and
a material of the third sub-layer comprises an organic material or an inorganic material.

10. The fabrication method according to claim 8, wherein a thickness of the fourth sub-layer is less than a thickness of the third sub-layer;
the thickness of the third sub-layer ranges from 50 Å to 1000 Å; and
the thickness of the fourth sub-layer ranges from 2 Å to 50 Å.

11. The fabrication method according to claim 6, further comprising, posterior to patterning the second emissive material layer, the second barrier material layer, and the second sacrificial material layer to form the second light-emitting structure, the second barrier portion, and the second sacrificial portion,
preparing a third emissive material layer on the substrate;
preparing a third barrier material layer on a side of the third emissive material layer facing away from the substrate by means of vacuum evaporation deposition;
preparing a third sacrificial material layer on a side of the third barrier material layer facing away from the substrate;
preparing a third etch protection layer on a side of the third sacrificial material layer facing away from the substrate, wherein the third etch protection layer comprises a plurality of spaced-apart third etch protection portions; and
patterning the third emissive material layer, the third barrier material layer, and the third sacrificial material layer to form a third light-emitting structure, a third barrier portion, and a third sacrificial portion in a region corresponding to each third etch protection portion.

12. The fabrication method according to claim 11, wherein a solubility of the third barrier portion in water is greater than or equal to 10⁻⁴ g/100 mL;
the solubility of the third barrier portion in water ranges from 10⁻⁴ to 10⁻² g/100 mL;
a material of the third barrier portion comprises an organic material or an inorganic material;
the inorganic material comprises a metal compound; and
the third barrier portion has a thickness of 50 Å to 1000 Å.

13. The fabrication method according to claim 11, wherein the third barrier material layer comprises a fifth material layer and a sixth material layer, and preparing the third barrier material layer on the side of the third emissive material layer facing away from the substrate by means of vacuum evaporation deposition comprises:
sequentially preparing the fifth material layer and the sixth material layer on the side of the third emissive material layer facing away from the substrate; and
patterning the third emissive material layer, the third barrier material layer, and the third sacrificial material layer comprises:
patterning the fifth material layer and the sixth material layer to form the third barrier portion, wherein the third barrier portion comprises a fifth sub-layer and a sixth sub-layer, and the sixth sub-layer is located on a side of the fifth sub-layer facing away from the substrate.

14. The fabrication method according to claim 13, wherein a solubility of the sixth sub-layer in water is lower than a solubility of the fifth sub-layer in water;
the solubility of the sixth sub-layer in water ranges from 10⁻⁴ to 10⁻² g/100 mL;
the solubility of the fifth sub-layer in water is greater than or equal to 0.1 g/100 mL;
a material of the sixth sub-layer comprises an inorganic material; and
a material of the fifth sub-layer comprises an organic material or an inorganic material.

15. The fabrication method according to claim 13, wherein a thickness of the sixth sub-layer is less than a thickness of the fifth sub-layer;
the thickness of the fifth sub-layer ranges from 50 Å to 1000 Å; and
the thickness of the sixth sub-layer ranges from 2 Å to 50 Å.

16. The fabrication method according to claim 11, further comprising, posterior to patterning the third emissive material layer, the third barrier material layer, and the third sacrificial material layer to form the third light-emitting structure, the third barrier portion, and the third sacrificial portion in the region corresponding to each third etch protection portion,
removing the first etch protection portion, the second etch protection portion, and the third etch protection portion;
removing the first sacrificial portion, the second sacrificial portion, and the third sacrificial portion; and
removing the first barrier portion, the second barrier portion, and the third barrier portion;
wherein removing the first sacrificial portion, the second sacrificial portion, and the third sacrificial portion comprises:
dissolving and removing the first sacrificial portion, the second sacrificial portion, and the third sacrificial portion using a solvent.

17. The fabrication method according to claim 16, wherein removing the first barrier portion, the second barrier portion, and the third barrier portion comprises:
dissolving and removing the first barrier portion, the second barrier portion, and the third barrier portion using a solvent;
the first barrier portion comprises a first sub-layer and a second sub-layer, and dissolving and removing the first barrier portion, the second barrier portion, and the third barrier portion using the solvent comprises:
dissolving and removing the first sub-layer using the solvent to peel off the second sub-layer;
the second barrier portion comprises a third sub-layer and a fourth sub-layer, and dissolving and removing the first barrier portion, the second barrier portion, and the third barrier portion using the solvent comprises:
dissolving and removing the third sub-layer using the solvent to peel off the fourth sub-layer; and
the third barrier portion comprises a fifth sub-layer and a sixth sub-layer, and dissolving and removing the first barrier portion, the second barrier portion, and the third barrier portion using the solvent comprises:
dissolving and removing the fifth sub-layer using the solvent to peel off the sixth sub-layer.

18. The fabrication method according to claim 16, further comprising, posterior to removing the first barrier portion, the second barrier portion, and the third barrier portion,
sequentially preparing a first carrier layer and a first electrode layer on the substrate;
wherein the first carrier layer comprises an electron transport layer and an electron injection layer.

19. The fabrication method according to claim 11, wherein the method further comprises, prior to preparing the first barrier material layer on the side of the first emissive material layer facing away from the substrate by means of vacuum evaporation deposition,
preparing a second carrier layer on the side of the first emissive material layer facing away from the substrate;
wherein the second carrier layer comprises a first hole blocking material layer;
the method further comprises, prior to preparing the second barrier material layer on the side of the second emissive material layer facing away from the substrate by means of vacuum evaporation deposition,
preparing a third carrier layer on the side of the second emissive material layer facing away from the substrate;
wherein the third carrier layer comprises a second hole blocking material layer; and
the method further comprises, prior to preparing the third barrier material layer on the side of the third emissive material layer facing away from the substrate by means of vacuum evaporation deposition,
preparing a fourth carrier layer on the side of the third emissive material layer facing away from the substrate;
wherein the fourth carrier layer comprises a third hole blocking material layer.

20. A display device, comprising:
a display panel fabricated by a fabrication method, the fabrication method comprising:
preparing a first emissive material layer on a substrate;
preparing a first barrier material layer on a side of the first emissive material layer facing away from the substrate by means of vacuum evaporation deposition;
preparing a first sacrificial material layer on a side of the first barrier material layer facing away from the substrate;
preparing a first etch protection layer on a side of the first sacrificial material layer facing away from the substrate, wherein the first etch protection layer comprises a plurality of spaced-apart first etch protection portions; and
patterning the first emissive material layer, the first barrier material layer, and the first sacrificial material layer to form a first light-emitting structure, a first barrier portion, and a first sacrificial portion in a region corresponding to each first etch protection portion.
